(19) United States
(12) Patent Application Publication
(10) Pub. No.: US 2026/0047484 A1
(43) Pub. Date: Feb. 12, 2026

(54) 3D CHIPLET INTEGRATION TECHNOLOGY

(71) Applicant: International Business Machines Corporation, Armonk, NY (US)

(72) Inventors: John Knickerbocker, Monroe, NY (US); Katsuyuki Sakuma, Fishkill, NY (US); Qianwen Chen, Chappaqua, NY (US)

(21) Appl. No.: 18/798,805

(22) Filed: Aug. 8, 2024

(51) Int. Cl. H01L 25/065; H01L 23/00; H01L 23/31; H01L 23/498

(52) U.S. Cl. CPC H01L 25/0652; H01L 23/3128; H01L 23/49816; H01L 24/16; H01L 24/27; H01L 24/29; H01L 24/32; H01L 24/73; H01L 2224/16225; H01L 2224/29082; H01L 2224/32225; H01L 2224/73204; H01L 2924/351

(57) ABSTRACT

An exemplary interconnect structure includes a first substrate, a second substrate vertically below the first substrate; and an underlayer structure between and in contact with the first and second substrates in which the underlayer structure between and in contact with the first and second substrates, a conductive connector between and electrically connecting the first and second substrates. The underlayer structure comprises an electromagnetic curable layer and a high thermal conductive layer and the underlayer structure laterally surrounds the conductive connector.

### BACKGROUND

The present invention relates generally to the electrical, electronic and computer arts and, more particularly, to 2.5D and 3D assembly structures and methods and the like.

A chiplet is a small, modular integrated circuit chip that performs a specific function very well (e.g. a memory block, an input/output driver, processor core or signal processing unit). One or more chiplets can be attached an interposer or the like into a single package. Forming chiplets in a package requires permanent bonding of the chiplets to other structures to become a chiplet layer on a silicon interposer (2.5D) or a chiplet in a 3D stack of chiplets.

### BRIEF SUMMARY

Principles of the invention provide techniques for creating a chiplet assembly structure and methods with electromagnetic curing. In one aspect, a first exemplary interconnect structure includes a first substrate, a second substrate vertically below the first substrate; and an underlayer structure between and in contact with the first and second substrates in which the underlayer structure comprises an electromagnetic curable layer.

In another aspect, an exemplary interconnect structure includes a first substrate, a second substrate vertically below the first substrate; and an underlayer structure between and in contact with the first and second substrates in which the underlayer structure between and in contact with the first and second substrates, a conductive connector between and electrically connecting the first and second substrates. The underlayer structure comprises an electromagnetic curable layer and a high thermal conductive layer and the underlayer structure laterally surrounds the conductive connector.

In still a further aspect, an exemplary method of forming an interconnect structure includes providing a first substrate, forming an electromagnetic curable layer on the first substrate, curing the electromagnetic curable layer, patterning the electromagnetic curable layer to form a first pattern, forming a conductive connector within at least a portion of the first pattern, providing a second substrate 220 and bonding the first substrate to the second substrate to form the interconnect structure.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
By using electromagnetic curable underfill material(s) in a 3D assembly higher thermal curing temperatures can be avoided which:
   lessens the warpage of the structure thereby reducing stress induced failures of the assembly caused by mismatched coefficients of expansion of materials in the structure,
   increases productivity by avoiding longer heating and cooling times,
   reduces or eliminated high temperature reflows (for example 250-260 C for lead free solder such as a Sn-Ag-Cu alloy) thereby avoiding large thermal expansion mismatch between Silicon (3 ppm) and laminate material / substrate (18 ppm),
   reduces bump movement either horizontally (x or y planes) and/or vertically (z plan) typically caused by bending or warpage of pad arrays of two components under thus improving interconnection yield, (5) reduces bump movement which allows scaling to small bumps, microbumps, metal structures, pads and pitch of these interconnection structures thereby providing higher interconnection density and higher bandwidth from the higher density, and
   allows optimization of stress to support stress testing or product function by balancing the upper bound of stress testing and lower stress level required to support reliability qualifications;
Electromagnetic curable underfill material(s) in a 3D assembly are compatible with copper-copper bonding, hybrid bonding, and solder bonding found in 3D assemblies;
By using multiple underfill materials (including electromagnetic curable underfill material), the underfill materials can be optimized for alignment accuracy of chiplets on an underlying structure;
By using multiple underfill materials (including electromagnetic curable underfill material), the underfill materials can be optimized for high thermal conductivity;
By using multiple underfill materials (including electromagnetic curable underfill material), the underfill materials can be optimized to accommodate high surface topography differences of the 3D structure;

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 depicts aspects of an exemplary interconnect structure in accordance with the prior art;

FIGS. 2A-2B depicts attachment of exemplary substrates to form an exemplary interconnect structure in accordance aspects of the present invention;

FIGS. 3A-3C depicts an exemplary interconnect structure in accordance aspects of the present invention;

FIGS. 4A-4C depicts exemplary cross-sections and top down views of substrates prior to attachment to form exemplary interconnect structure in accordance aspects of the present invention;

FIGS. 5A-5C depicts exemplary cross-sections and top down views of substrates prior to attachment to form exemplary interconnect structure in accordance aspects of the present invention;

FIGS. 6A-6C depicts exemplary cross-sections and top down views of substrates prior to attachment to form exemplary interconnect structure in accordance aspects of the present invention;

FIG. 7 depicts an exemplary interconnect structure in accordance aspects of the present invention; and FIG. 8 depicts an exemplary interconnect structure in accordance aspects of the present invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

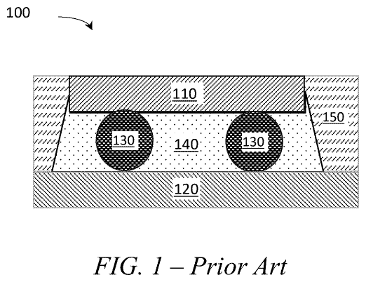

FIG. 1 depicts an exemplary prior art interconnect structure 100. The structure includes an upper substrate 110, a lower substrate 120, and connections 130 between the upper and lower substrates. Surrounding the connections 130 is a single underfill layer 140. A molding compound 150 encases the underfilled layer 140 (e.g. thermal curable epoxy resin) and is in contact with each of the upper and lower substrates. The two substrates can be bonded together using pressure and heat. However, due to differences in the coefficient of thermal expansion (CTE) of the various materials, heating can lead to stress and non-planarity of the structure which can adversely impact yield and/or reliability. In addition, accurately positioning one substrate above another so that input/output (I/O) pads on a substrate align with the connection 130 is becoming more challenging with increasing I/O size accompanied by decreasing I/O pitch.

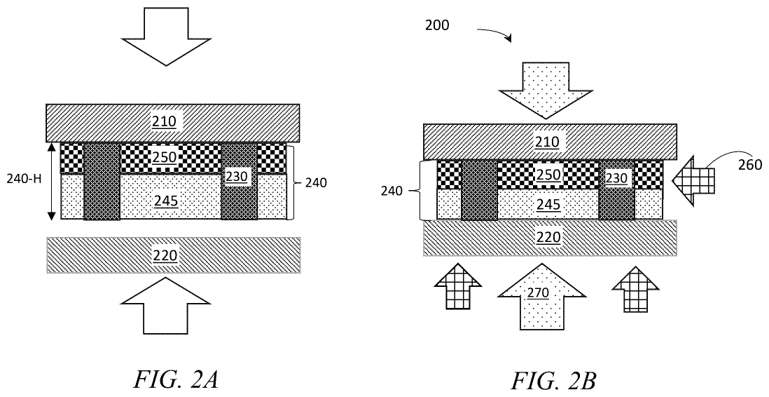

Aspects of invention provide techniques for an interconnect structure and methods of creating the same. Referring to FIG. 2A, an exemplary technique for creating an interconnect structure includes providing a first substrate 210 and a second substrate 220. The first substrate 240 can have an underlayer structure 240 which surrounds conductive connectors 230. In FIG. 2B, the two substrates are pressed 270 together and cured 260 with electromagnetic radiation (EMR) to form the interconnect structure 200. EMR of underlay structure 240 can be completed at room temperature, or optionally at a temperature to aide in stress reduction for reliability testing or at a temperature to aide product application optimization. The optional thermal heating can advantageously occur at temperatures less than or equal to solder reflow temperatures. Exemplary solder reflow temperatures can be (e.g., greater than 300 C for a PbSn solder, about 220 C to 231 C for SnAgCu with reflow such as 250 C to 260 C, or about 190 C to 220 C for Bi containing lead free solder. Similarly, underlay structure 240 cure at room temperature can avoid thermal cure of adhesives such as 125 C to about 160 C. Depending on underlayer structure 240, use of optional thermal curing can be completed with temperatures such as 125 C to 180 C where lower temperatures typically require longer times of 20 min to 60 min and higher temperatures require less time such as <5 min or 5 min to 10 min. Electromagnetic curing can occur from the top, bottom, and or sides, can be directed uniformly, in a line scan or to a spot(s). Use of room temperature or low temperature of <150 C may be advantageous. Samples can also be batch preconditioned to prepare samples, bake out moisture or use vacuum/low pressure and then can support a room temperature or low temperature bonding as standard process.

Each of the first substrate 210 and the second substrate 220 can be anyone of a die (including a chiplet); an interposer, a handler wafer (silicon or glass), a laminate, or the like. In addition, other components including but not limited to decoupling capacitors, inductors, voltage regulators, optical components or other components, and lids can be joined with the same methodology and therefore be one or both of the first substrate 210 and the second substrate 220. The first and second substrates can be the same type of structure (e.g. die on die) or different types of structures (e.g. die on interposer).

The underlayer structure 240 as depicted in exemplary FIGS. 2A and 2B include an electromagnetic curable layer 245 and a second underlayer 250 material. An electromagnetic curable layer 245 is one that can be exposed to targeted electromagnetic radiation to induce film activation such as cross-linking. Radiation parameters such as wavelength, source, intensity and time should be selected which do not ablate the underlayer structure 240. Electromagnetic radiation (EMR) can use different wavelengths of EMR such as but not limited to ultraviolet (UV), white light or infrared (IR). The EMR can be delivered with a uniform exposure across the area to be cured with targeted intensity and time with appropriate wavelength or range of wavelengths, (blanket approach), alternatively a scanning laser often with smaller spot size or scan line can be scanned across a portion or area to be cured with appropriate intensity, wavelength(s) and rate or duration. Other options of pulse duration and other laser parameters can be applied. For purposes of this disclosure, EMR curing is by electromagnetic radiation causing curing of polymer such as cross linking, absorption of light to create heat that causes curing or other mechanisms of polymer curing. Note the sample can remain at room temperature for these EMR curing processes or may see a small increase in temperature. The EMR may take seconds or minutes to complete curing. EMR curing can be distinguished from thermal curing in that for thermal curing the sample is placed into an oven and typically at 125 C to 175 C temperature and for some time period the solvent is typically removed and then the adhesive is cured. For thermal curing, the combination of heating times and holding at high temperature and cooling time, can be measured in longer times of double digit minutes or hours. By way of example, and not limitation, the electromagnetic curable layer 245 can be HD-4100 or HD7204, or NTT E 3876 or NTT ER 4198 or SU-8 or alternate materials with electromagnetic radiation ability to cure the material polymer chain(s) in combination of a prior bake out step to remove solvents that can be used to apply the adhesive. Alternatively, additives can be composition of the adhesive to absorb electromagnetic energy and directly or indirectly lead to curing of the adhesive. Note EMR may be used such as UV light or laser such as but not limited to 365 nm lambda. Alternatively, IR laser with wavelength in the range of 1000 nm to 5000 nm may be used to cure the adhesive. Alternatively, specific colors of light or white light may be applied to cure the adhesives or subsets of the adhesives. Alternatively EMR only, EMR and Thermal heat treatments or Thermal curing only may be used to cure the adhesives. Note that industry available materials or new compositions or custom materials may be developed to support EMR curing. It is contemplated that EMR absorbing materials may be added to the electromagnetic curable layer 245 or the second underlayer 250 material to enhance EMR curing. Non-limiting examples of additive materials include various polymer compositions. One possible specific non-limiting example is bis-benzimidazoles molecules including a phenoxy base material such as a bisbenzimidazole of pyridine (e.g. 2, 5-Bis(2-benzimidazolyl)-pyridine). Alternatively, a distribution of small EMR absorbing particles, films, or other shapes can be used such as Carbon or Titanium or Aluminum, SiO2, SiN, TiO2 or combinations of polymer composition and absorbing particles or materials.

Furthermore in this regard, for the phenoxy composition with polymer curable material, it would be appropriate in one or more embodiments to characterize same with different wavelengths of electromagnetic radiation to verify functioning with X-ray, UV-light, visible light, and IR light. In addition to polymer curing such as a phenoxy material, one or more embodiments can make use of polyimide materials, epoxy materials, fluorinated polyimide materials, and the like. Curing of the adhesive materials could be carried out with, purely by way of example and not limitation, with EMR, or EMR and low temperature cure, or low temperature cure. Another pertinent aspect includes the bonding of the interconnects, such as solder to pad, solder to solder, or Cu to Cu, by using EMR, EMR and low temperature, or low temperature to create electrical interconnects. In one or more embodiments, it will be appropriate to optimize laser lambda, energy level, and perimeter doping of the interconnection to be able to transfer EMR energy to pulse heat the interconnections for bonding. Suitable lambda absorbing materials include carbon black, Ti, Al, or other materials.

The second underlayer 250 material can be an adhesive, polyimide (PI), photosensitive polyimide (PSPI), or a high thermal conductive material such as SiC, AlN, SiN, diamond film or the like. The underlayer structure 240 has a height 240-H, in the FIG. 2A example the second layer is less than 50% of the height, but it could be equal to or more than 50% of the height. It is also possible that the entire underlayer structure 240 is the single electromagnetic curable layer 245, meaning there is no second underlayer 250 material. Further variations of exemplary underlayer structure 240 are discussed in connection with subsequent figures.

The conductive connector 230 can be a pillar, via, or solder ball. The conductive connector 230 can have a diameter from 1 to 100 um and can be W, Mo, Cu, Solder, Ni, Au, Ti, W, Mo, combinations thereof or other suitable materials. One or more of the conductive connectors 230 can function to provide an electrical connection between the substrates. Another of the one or more conductive connectors 230 can function as thermal conductors to remove heat from the interconnect structure 200.

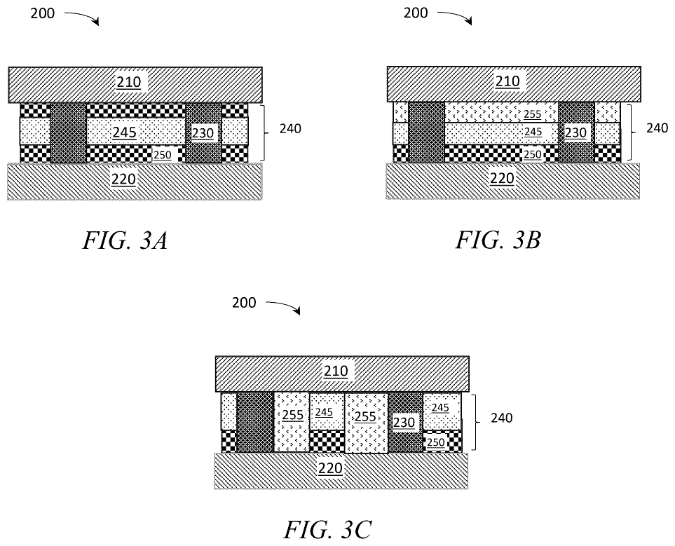

FIGS. 3A-3C depict further variations of exemplary underlayer structure 240. Here, there are three layers. In FIG. 3A, the three layers of underlayer structure 240 are a sandwich of electromagnetic curable layer 245 between second underlayer 250 material. One recognizes that the sandwich could also be reversed such that the second underlayer 250 material is between two layers electromagnetic curable layer 245. In FIG. 3A, the three layers are different materials, namely, the electromagnetic curable layer 245, a second underlayer 250 material, and third underlayer 255 material. Here, if the second underlayer 250 material is an adhesive, polyimide (PI), or photosensitive polyimide (PSPI), then the third underlayer 255 material is a high thermal conductive material such as SiC, AlN, SiN, diamond film or the like. The three layers can be in any order. In FIGS. 3A-3B, the three layers can be deposited on the first substrate 210 and one photolithography and etch sequence can be used to form openings subsequently filled with con conductive connector 230 and polished. In this way, the materials first substrate's surface are co-planar and can be hybrid bonded to pads (not shown) in the second substrate 220.

In the exemplary underlayer structure 240 of FIG. 3C, two of the three layers are deposited on the first substrate 210 and then photolithographically patterned and etched to form openings which are filled with the third underlayer 255 material. The substrate is planarized and s photolithography/etching sequence forms openings subsequently filled by conductive connector 230 which is polished to form a co-planar surface of the first substrate 210. In the variation of underlayer structure 240 arrangement of FIG. 3C, advantageously, the third underlayer 255 can be a high thermal conductive material such as SiC, AlN, SiN, diamond film or the like to aid in removing heat from conductive connector 230. Alternatively, the first photolithography/etch sequence can be used to create openings for the conductive connector 230 which is deposited in the opening and polished to form a co-planar surface of the first substrate 210. Then the second photolithography/etch sequence can form openings in the electromagnetic curable layer 245 and the second underlay 250 adjacent the in the conductive connector 230. However, instead of filling with a material (e.g. third layer 255), the openings remain. The remaining openings (or micro-channels) can be used for cooling purposes (e.g. fluidic or two-phase cooling).

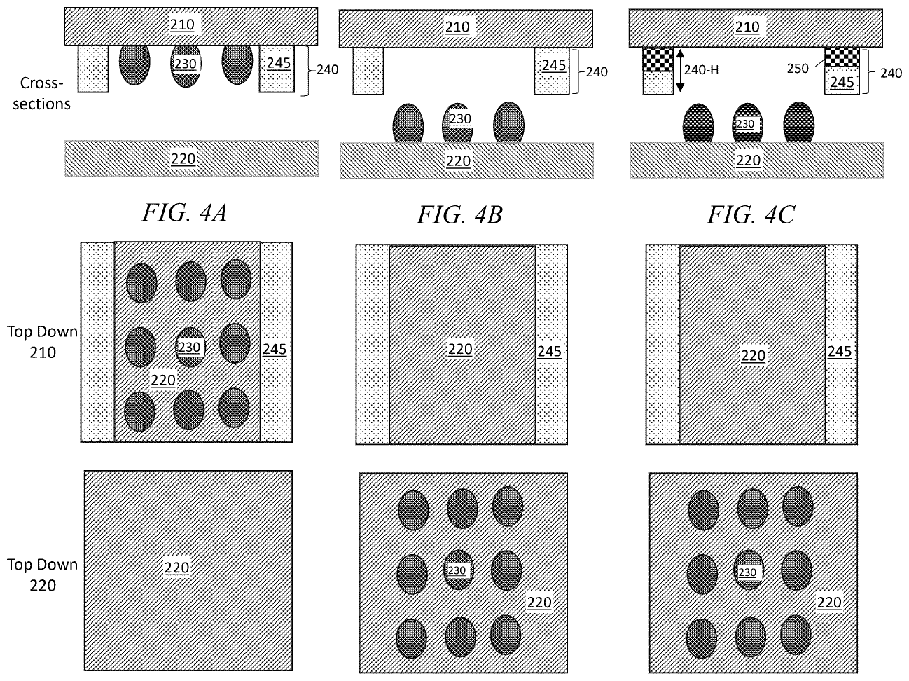

FIGS. 4A-4C depict yet another variation of exemplary underlayer structure 240. Here, the top row shows an exemplary cross-section for each embodiment, while the underlying rows show exemplary top-down views of the first substrate 210 and second substrate 220 for their respective embodiment of FIGS. 4A-4C. In FIGS. 4A-4C the underlayer structure 240 is patterned to have edges which act as a guide for aligning placement of one substrate to another (e.g. FIG. 4B), the edges also minimize die shifting which may occur following reflow in the case in which conductive connector 230 include solder. In FIG. 4A, the underlayer structure 240 is depicted as a single layer of electromagnetic curable layer 245 which is on the same substrate as the conductive connector 230 prior to pressure joining the two substrates and reflowing the solder (note, curing of electromagnetic curable layer 245 can occur prior to substrate joining). As FIG. 4B illustrates, in some embodiments, the underlayer structure 240 and the conductive connector 230 could be on opposing substrates prior to joining. As FIG. 4C illustrates, in some embodiments, the underlayer structure 240 can include more than one layer, in this example the electromagnetic curable layer 245 and the second underlayer 250 material. FIG. 4C shows both the electromagnetic curable layer 245, and the second underlayer 250 material on the same substrate, but one patterned layer could be on first substrate 210 and the other patterned layer on the second substrate 220 prior to joining.

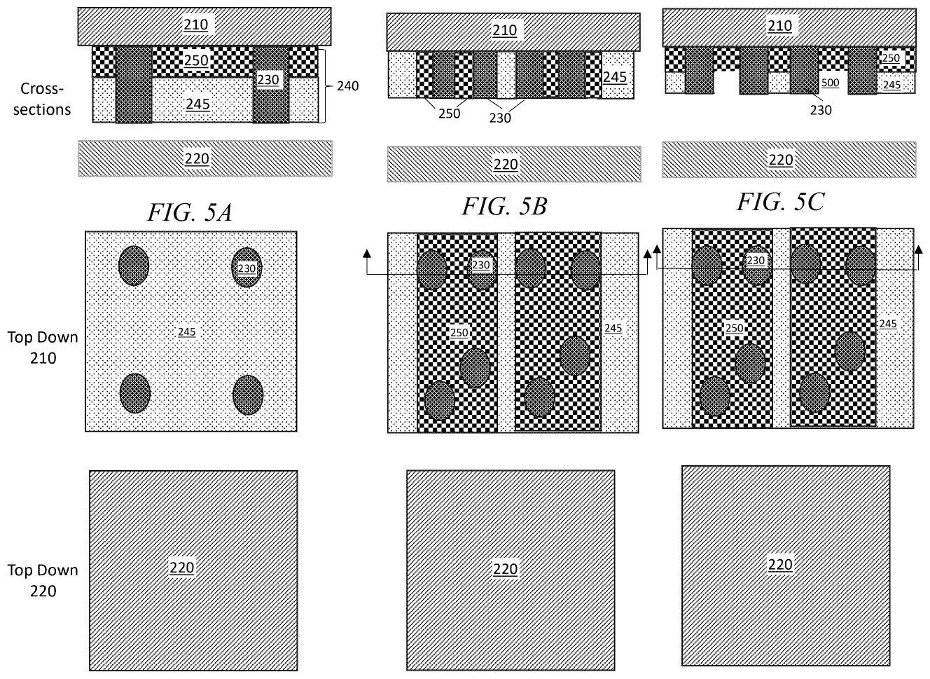

FIGS. 5A-5C depict yet another variation of exemplary underlayer structure 240. Here, the top row shows an exemplary cross-section for each embodiment, while the underlying rows show exemplary top-down views of the first substrate 210 and second substrate 220 for their respective embodiment of FIGS. 5A-5B. FIG. 5A is similar to the embodiment of FIG. 2A in which the underlayer structure 240 includes two layers, but includes top-down perspectives. FIGS. 5B and 5C show a two layer underlayer structure 240 embodiment which requires two lithography/etch sequences similar to those described in conjunction with FIG. 3C. In FIG. 5B the resulting first substrate 210 is planar and amenable to hybrid bonding to the second substrate 220. In FIG. 5C the resulting first substrate 210 has microchannels 500, and while not a planar surface it can still be hybrid bonded to the second substrate 220. Again, the order of the arrangement of the layers within the underlayer structure 240 can be swapped and/or a third layer 255 added to the first or second substrate.

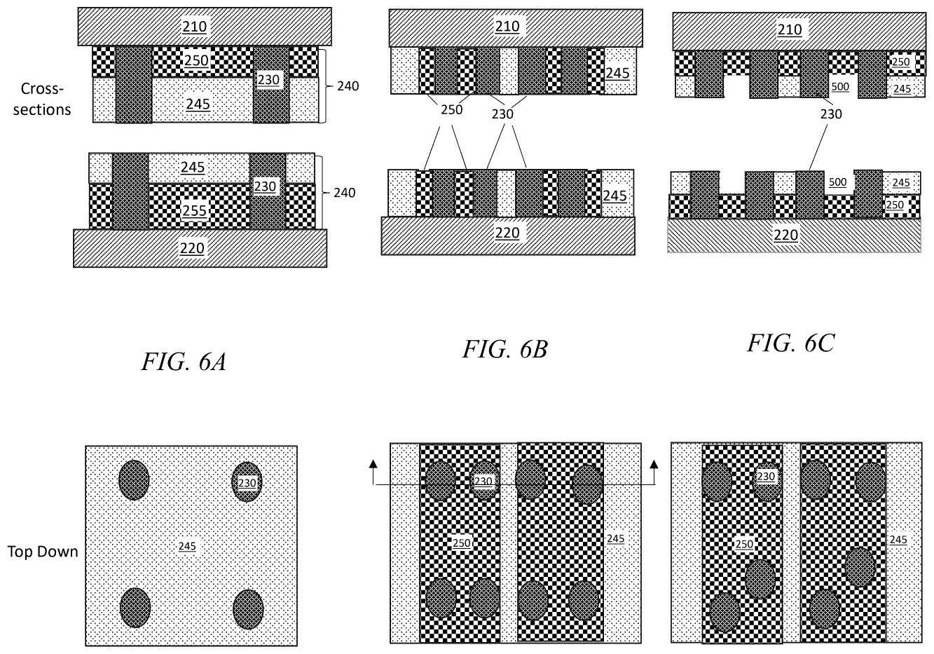

FIGS. 6A-6C show that the substrates can be mirror images of each other prior to joining.

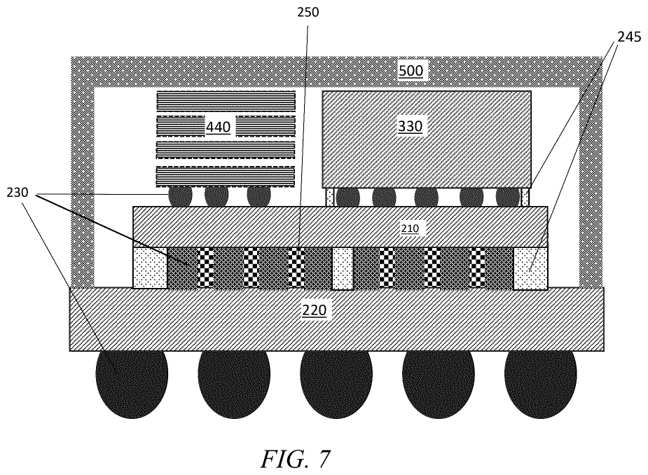

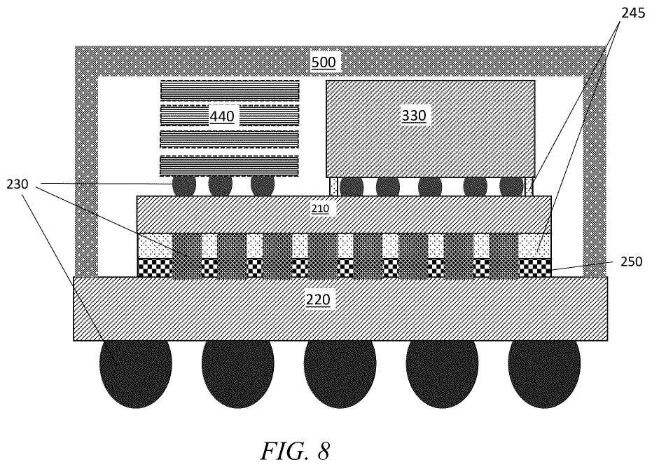

FIGS. 7 and 8 shows an exemplary interconnect structure having more than two substrates and how the various configurations can be mixed in matched. In FIG. 7, first substrate 210 and second substrate 220 have an underlayer structure similar to FIG. 5B. In addition, third substate 330 is joined to the first substrate 210 with an underlayer structure similar to FIG. 4A or 4B. A fourth substrate 440 also joined to the first substrate 210. A housing 500 can enclose the substrates. In FIG. 8, first substrate 210 and second substrate 220 have an underlayer structure similar to FIG. 5A. In addition, third substate 330 is joined to the first substrate 210 with an underlayer structure similar to FIG. 4A or 4B. A fourth substrate 440 also joined to the first substrate 210. A housing 500 can enclose the substrates.

In summary, in one aspect, a first exemplary semiconductor structure includes a first substrate 210, for example a chiplet or component or substrate, with at least one conductive connector 230 (for example, one or more of an array of solder bumps, an array of micropillars with solder, or an array of metal pads). A second substrate 220 having structures aligning with the conductive connector 230 of to the first substrate 210 (e.g. chiplet, or component or substrate) and an underlayer structure 240 that contact each of first substrate 210 and a second substrate 220.

In another aspect, the underlayer structure 240 can be cured using electromagnetic energy at room temperature, below room temperature or above room temperature or can be cured using electromagnetic radiation, thermal curing or a combination therein.

In still a further aspect, an exemplary method of forming a semiconductor array structure includes use of a means to activate conductive connector 230 (e.g. the array of array of solder bumps, an array of micropillars with solder, or an array of metal pads) with plasma activation and then permanent adherence between the two substrates is made with the use of energy transfer such laser assisted bonding at lower than room temperature, room temperature or above room temperature or alternate method such as, thermal compression bonding, thermal reflow or alternate method or combinations therein.

Optionally, the one or more structures and methods above can be repeated sequentially for additional substrate integration and /r multi-substrates can be processed in parallel.

In another aspect an exemplary interconnect structure includes a first substrate 210, a second substrate 220 vertically below the first substrate, and an underlayer structure 240 between and in contact with the first and second substrates in which the underlayer structure comprises an electromagnetic curable layer 245. Optionally, the electromagnetic curable layer 245 comprises one or more of HD-4100, HD7204, NTT E 3876, NTT ER 4198 or Su8. Optionally, the first substrate 210 comprises one or more of a die, a chiplet, an interposer, a handler wafer, a laminate, a component, an optical component and a lid. Optionally the second substrate 220 comprises one or more of a die, a chiplet, an interposer, a handler wafer, a laminate, a component, an optical component and a lid. Optionally, interconnect structure further includes at least one conductive connector 230 in contact with the first substrate 210 and the second substrate 220 and laterally surrounded by the underlayer structure 240. Optionally, the underlayer structure 240 is in contact with and co-planar with the at least one conductive connector. Optionally, the at least one conductive connector is a pillar. Optionally, the at least one conductive connector is a solder ball. Optionally, the underlayer structure 240 further comprises a second underlayer 250 material which can include one or more of an adhesive, polyimide (PI), photosensitive polyimide (PSPI), SiC, AlN, SiN, diamond film. Optionally, the underlayer structure 240 further comprises a third underlayer 255 material can include one or more of an adhesive, polyimide (PI), photosensitive polyimide (PSPI), SiC, AlN, SiN, diamond film and is different from the second underlayer 250 material. Optionally, the second underlayer 250 material is in contact with the first substrate 210 and the electromagnetic curable layer 245. Optionally, the second underlayer 250 material is in contact with the first substrate 210 and the second substrate 220. Optionally, the interconnect structure further includes a third substrate 330 vertically above the first substrate 210, a second group of conductive connectors 230 electrically connects the first and third substrates, and a second electromagnetic curable layer 245 between the first and third substrates.

In another aspect an exemplary interconnect structure includes a first substrate 210, a second substrate 220 vertically below the first substrate, an underlayer structure 240 between and in contact with the first and second substrates, and a conductive connector between and electrically connecting the first and second substrates in which the underlayer structure comprises an electromagnetic curable layer 245 and a high thermal conductive layer and the underlayer structure laterally surrounds the conductive connector. Optionally, the high thermal conductive layer is at least 50% of a height of the conductive connector. Alternatively, the high thermal conductive layer is less than 50% of a height of the conductive connector. Optionally the high thermal conductive layer includes a microchannel.

In an aspect an exemplary method of making an interconnect structure includes providing a first substrate 210, forming an electromagnetic curable layer 245 on the first substrate, curing the electromagnetic curable layer 245, patterning the electromagnetic curable layer 245 to form a first pattern, forming a conductive connector 230 within at least a portion of the first pattern, providing a second substrate 220, and attaching the first substrate to the second substrate to form the interconnect structure.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about”means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F. R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. An interconnect structure comprising:
a first substrate;
a second substrate vertically below the first substrate; and
an underlayer structure between and in contact with the first and second substrates; and
wherein the underlayer structure comprises an electromagnetic curable layer.

2. The interconnect structure of claim 1, wherein the electromagnetic curable layer comprises one or more of HD-4100, HD7204, NTT E 3876, NTT ER 4198 or Su8.

3. The interconnect structure of claim 1, wherein the first substrate comprises one or more of a die, a chiplet, an interposer, a handler wafer, a laminate, a component, an optical component and a lid.

4. The interconnect structure of claim 1, wherein the second substrate comprises one or more of a die, a chiplet, an interposer, a handler wafer, a laminate, a component, an optical component and a lid.

5. The interconnect structure of claim 1 further comprises at least one conductive connector in contact with the first substrate and the second substrate and laterally surrounded by the underlayer structure.

6. The interconnect structure of claim 5, wherein the underlayer structure is in contact with and co-planar with the at least one conductive connector.

7. The interconnect structure of claim 5, wherein the at least one conductive connector is a pillar.

8. The interconnect structure of claim 5, wherein the at least one conductive connector is a solder ball.

9. The interconnect structure of claim 5, wherein the underlayer structure further comprises a second underlayer material.

10. The interconnect structure of claim 9, wherein the second underlay material comprises one or more of an adhesive, polyimide (PI), photosensitive polyimide (PSPI), SiC, AlN, SiN, diamond film.

11. The interconnect structure of claim 9, wherein the underlayer structure further comprises a third underlayer material.

12. The interconnect structure of claim 11, wherein the third underlay material comprises one or more of an adhesive, polyimide (PI), photosensitive polyimide (PSPI), SiC, AlN, SiN, diamond film and is different from the second underlayer material.

13. The interconnect structure of claim 9, wherein the second underlayer material is in contact with the first substrate 210 and the electromagnetic curable layer.

14. The interconnect structure of claim 9, wherein the second underlayer material is in contact with the first substrate and the second substrate.

15. The interconnect structure of claim 5 further comprising:
a third substrate vertically above the first substrate;
a second group of conductive connectors electrically connects the first and third substrates; and
a second electromagnetic curable layer between the first and third substrates.

16. An interconnect structure comprising:
a first substrate;
a second substrate vertically below the first substrate; and
an underlayer structure between and in contact with the first and second substrates; and
a conductive connector between and electrically connecting the first and second substrates;
wherein the underlayer structure comprises an electromagnetic curable layer and a high thermal conductive layer; and
wherein the underlayer structure laterally surrounds the conductive connector.

17. The interconnect structure of claim 16 wherein the high thermal conductive layer is at least 50% of a height of the conductive connector.

18. The interconnect structure of claim 16 wherein the high thermal conductive layer is less than 50% of a height of the conductive connector.

19. The interconnect structure of claim 16 wherein the high thermal conductive layer comprises a microchannel.

20. A method of forming an interconnect structure comprising:
providing a first substrate;
forming an electromagnetic curable layer on the first substrate;
curing the electromagnetic curable layer;
patterning the electromagnetic curable layer to form a first pattern;
forming a conductive connector within at least a portion of the first pattern;
providing a second substrate; and
bonding the first substrate to the second substrate to form the interconnect structure.
